(19) United States
(12) Patent Application Publication
(10) Pub. No.: US 2007/0199656 A1
(43) Pub. Date: Aug. 30, 2007

(54) HYBRID WAFER-HOLDER

(75) Inventors: William Leavitt, Haverhill, MA (US); Steven Richards, Georgetown, MA (US)

Correspondence Address: NUTTER MCCLENNEN & FISH LLP, WORLD TRADE CENTER WEST, 155 SEAPORT BOULEVARD, BOSTON, MA, 02210-2604, US

(73) Assignee: IBIS TECHNOLOGY CORPORATION, Danvers, MA (US)

(21) Appl. No.: 11/680,154

(22) Filed: Feb. 28, 2007

Related U.S. Application Data
(60) Provisional application No. 60/777,581, filed on Feb. 28, 2006.

(51) Int. Cl. H01L 21/306

(52) U.S. Cl. 156/345.11

(57) ABSTRACT

Wafer-holding structures formed from thermosetting resins are disclosed for use in semiconductor processing including, for example, SIMOX wafer processing. At least a portion of the distal portion of the holder comprises graphite, thereby reducing wafer rotation during implantation while maintaining the desired overall thermal signature provided by the thermosetting resin. In one embodiment a pin is disclosed that is adapted to receive a wafer edge, and is coupled with a wafer holder assembly. The pin can be filled with a conductive material to provide an electrical pathway between the wafer and the wafer holder assembly, which can be coupled to a ground. This arrangement provides a conductive path for inhibiting electrical discharges from the wafer during the ion implantation process. The pin exhibits thermal isolation characteristics and sufficient hardness so as to not effect localized thermal dissipation of the wafer, yet is sufficiently soft so as to not mark or otherwise damage the wafer.

### RELATED APPLICATION

The present invention claims priority to a provisional application entitled “Hybrid Wafer-Holder,” filed on Feb. 28, 2006 and having a Ser. No. 60/777,581. This provisional application is herein incorporated by reference in its entirety.

### BACKGROUND OF THE INVENTION

The present invention relates generally to silicon wafer processing, and more particularly, to devices for holding silicon wafers as they are subjected to ion bombardment and to heat treatment.

Various techniques are known for processing silicon wafers to form devices, such as integrated circuits. One technique includes implanting oxygen ions into a silicon wafer to form buried layer devices known as silicon-on-insulator (SOI) devices. In these devices, a buried insulation layer is formed beneath a thin surface silicon film. These devices have a number of potential advantages over conventional silicon devices (e.g., higher speed performance, higher temperature performance and increased radiation hardness). The lesser volume of electrically active semiconductor material in SOI devices, as compared with bulk silicon devices, tends to reduce parasitic effects such as leakage capacitance, resistance, and radiation sensitivity.

In one known technique, known by the acronym SIMOX, a thin layer of a monocrystalline silicon substrate is separated from the bulk of the substrate by implanting oxygen ions into the substrate to form a buried dielectric layer. This technique of “separation by implanted oxygen” (SIMOX), provides a heterostructure in which a buried silicon dioxide layer serves as a highly effective insulator for surface layer electronic devices.

In the SIMOX process, oxygen ions are implanted into silicon, after which the material is annealed to form the buried silicon dioxide layer or BOX region. The annealing phase redistributes the oxygen ions such that the silicon/silicon dioxide boundaries become more abrupt, thus forming a sharp and well-defined BOX region, and heals damage in the surface silicon layer caused by the ion bombardment.

During the SIMOX process, the wafers are subjected to relatively severe conditions. For example, the wafers are typically heated to temperatures of about 500-600 degrees Celsius during the ion implantation process. Subsequent annealing temperatures are typically greater then 1000 degrees Celsius. In contrast, most conventional ion implantation techniques are conducted at temperatures less than 100 degrees Celsius. In addition, the implanted ion dose for SIMOX wafers is in the order of 1×10¹⁸ ions per square centimeter, which can be two or three orders of magnitude greater than some known techniques.

Conventional wafer-holding devices are often incapable of withstanding the relatively high temperatures associated with SIMOX processing. Besides the extreme temperature conditions, in rotatable ion implantation systems a secure wafer gripping problem arises. Furthermore, wafer-holding structures having exposed metal are ill-suited for SIMOX processes because the ion beam will induce sputtering of the metal and, thus, result in wafer contamination. In addition, the structure may deform asymmetrically due to thermal expansion, which can damage the wafer surface and/or edge during high temperature annealing so as to compromise wafer integrity and render it unusable.

Another disadvantage associated with certain known wafer holders is electrical discharge of the wafers. If a wafer holder is formed from electrically insulative materials, the wafer will become charged as it is exposed to the ion beam. The charge build up disrupts the implantation process by stripping the ion beam of space charge neutralizing electrons. The charge built-up on the wafer can also result in a discharge to a nearby structure via an electrical arc, which can also contaminate the wafer or otherwise damage it.

Another disadvantage associated with conventional wafer holders in rotatable ion implantation systems is the lack of secure and efficient wafer gripping. Failure to secure a wafer against the centrifugal forces that are present in a rotatable system can result in damage to the wafer. If a wafer is not precisely placed and secured in the wafer holder, the wafer can fall out of the wafer holder assembly or otherwise be damaged during the load, unload, or ion implantation steps.

Even when the wafer is held secure, many techniques cause other damage to the wafer during the ion implantation process. For example, holding pins can crush when securing the wafer causing localized thermal drifts much like a heat sink thus damaging wafer integrity. Wafer-holding pins formed of hard materials can leave marks on the wafer, yet pins formed of soft materials can stick to the wafer; neither situation is desirable.

Another disadvantage associated with some existing wafer holders is shadowing. Shadowing is encountered when wafer holder structures obstruct the path of the ion beam, and thereby prevent implantation of the shadowed wafer regions. This deprivation of usable wafer surface area is a common problem in wafer holders that do not reduce the profile of their structural components.

Leavitt et al. (U.S. Pat. No. 6,794,662) discloses a device for holding a wafer which addresses several of the problems associated with conventional wafer-holding structures. Leavitt discloses a polymeric pin that is adapted to receive a wafer edge and is coupled with a wafer holder assembly. The preferred thermosetting resin pins disclosed by Leavitt can be filled with a conductive material to provide an electrical pathway between the wafer and the wafer holder assembly, which can be coupled to a ground. Such an arrangement provides a conductive path for inhibiting electrical discharges from the wafer during the ion implantation process. The Leavitt pin exhibits thermal isolation characteristics and sufficient hardness so as to not effect localized thermal dissipation of the wafer, yet is sufficiently soft as to not mark or otherwise damage the wafer. While Leavitt provides an improved wafer-holding pin as compared to conventional structures, one potential disadvantage of the polymer-based pins is that they may permit some wafer rotation during implantation.

It would, therefore, be desirable to provide a wafer holder that is able to withstand the relatively high temperatures and energy levels associated with SIMOX wafer processing while also reducing the potential for arcing and shadowing and providing an improved wafer-gripping capability.

### SUMMARY OF THE INVENTION

The present invention provides improved polymeric wafer-holding structures that maintain their structural integrity, prevent the build up of electrical charge on the wafer, and prevent wafer slippage during high temperature semiconductor processing.

Although the invention is primarily shown and described in conjunction with SIMOX wafer processing, it is understood that the wafer-holding pin has other applications relating to implanting ions into a substrate and to wafer processing in general.

In one aspect of the invention, wafer-holders are described that are formed from a polymeric material, e.g., a thermosetting resin material, wherein at least a portion of the holder comprises graphite and/or other high surface friction materials. The holder can be used to hold a wafer in a vacuum environment at a temperature of between about 0° C. and about 650° C. The thermosetting material is able to withstand an oxygen ion beam without substantial oxidation. The holder has distal and proximal portions, where the distal portion can be adapted to hold the wafer via a groove that is sized and shaped to receive an edge of the wafer. The proximal portion is adapted to couple with a wafer-holding assembly.

In one embodiment, the wafer-holder can be a pin having a distal portion that includes a head coupled to a flange with a wafer-receiving groove therebetween. The groove can be adapted to engage an edge of the wafer and can have an inner surface that is partially curved, e.g., it can be shaped as a portion of a cylindrical surface. At least a portion of the groove can comprise graphite or other high surface friction materials. The inner surface can exhibit a radial symmetry about an axis for an azimuthal angle of at least 10 degrees.

In a further aspect of the invention, the wafer-holding pin provides a conductive path from the wafer to the assembly, which can be coupled to ground. By grounding the wafer, any build up of electrical charge on the wafer is inhibited for preventing potentially damaging electrical arcing from the wafer during the ion implantation process. In an exemplary embodiment, the polymeric pin can be filled with an electrically conductive material, for example, carbon. The material provides electrical conductivity for the wafer-holding pin to achieve optimal SIMOX wafer processing conditions.

In another aspect of the invention, the wafer-holding pins can have a geometry that reduces the need for precise alignment and provides a simpler wafer gripping capability. These pins facilitate wafer placement into the wafer holder, and pin coupling to the wafer holder assembly. In one embodiment, the pins can have a proximal portion for coupling to a base structure of the wafer-holding assembly, and a distal portion for holding the wafer. The distal end of the pin is further defined by having a longitudinal axis extending from the distal portion towards the proximal end. The distal portion is at least partially radially symmetric about the longitudinal axis (or a line parallel thereto), and has a wafer-receiving groove disposed between a head and a flange. The wafer-receiving groove preferably contacts only part of the wafer edge, e.g., only the top and bottom of the wafer edge, and at least a portion of the groove can comprise graphite.

Due to the cylindrical symmetry of the distal portion, the need for precise pin alignment with the wafer is relaxed. The pins are able to engage a wafer across a much wider angle of approach. Thus, the radial symmetry reduces the need for precision in aligning the pins when they are attached to the other elements of the wafer-holding assembly.

In addition, the wafer-receiving groove contacts top and bottom regions of the wafer edge such that the area of the pin in contact with the wafer edge is reduced. This reduces arcing between the wafer edge and the pin during the ion implantation process.

The geometry of the head of the distal portion can also be effective in reducing the pin profile, by reducing the amount of pin material proximate the wafer. This has the effect of reducing not only arcing but also shadowing, thereby facilitating ion implantation of the entire wafer surface area.

In a further aspect of the invention, an ion implanter with a wafer-holding assembly uses a pin comprising a thermosetting resin material suitable for use in a vacuum environment operating at a temperature of about 0° C. to about 650° C., and is able to withstand an oxygen ion beam without substantial oxidization. At least a portion of the pin comprises graphite.

In another aspect, a wafer-holding pin for use in an ion implantation system includes a distal portion adapted to hold a wafer during exposure to an ion beam and comprising a thermosetting resin material able to withstand the ion beam. The distal portion can also include an anchoring site for frictionally engaging the wafer. The anchoring site can comprise a material exhibiting a coefficient of friction with the wafer greater than a respective coefficient exhibited by the resin material. The wafer-holding pin can further include a proximal portion that is adapted to couple with a wafer-holding assembly.

In another aspect, a wafer-holding pin is disclosed that can include a distal portion for holding a wafer comprising a thermosetting resin material suitable for use in a vacuum environment at a temperature in a range of about 0° C. and about 650° C. and able to withstand an oxygen ion beam without substantial oxidation. The distal portion can be electrically conductive to provide an electrical pathway between the wafer and a wafer-holding assembly. The pin can further include a proximal portion adapted to couple to the wafer-holding assembly. A longitudinal axis of the pin can extend from the distal portion towards the proximal portion. The distal portion can further include a head that is coupled to a flange with a wafer-receiving groove therebetween. The groove can be adapted to engage an edge of the wafer and can have a curved inner surface. At least a portion of the inner surface can be formed of a material that is different than the resin and that is suitable for frictionally securing the wafer to the distal portion.

In yet another aspect, a wafer-holding pin for use in an ion implanter can include a distal portion comprising a wafer-receiving groove, a proximal portion adapted for coupling with a wafer-holding assembly, and a thermally conductive insert disposed in said distal portion such that a surface portion of said insert provides an anchoring site for the wafer in the groove. The insert can further provide a thermal path for transferring heat to the wafer.

In a further aspect of the invention, a wafer-holding pin for use in an ion implanter can include a body having an electrically conductive distal portion for holding a wafer in a path of an ion beam and providing a thermal path for transferring heat to the wafer. The body can also include a proximal portion adapted for coupling with a wafer holding assembly. The wafer-holding pin can further include a sheath that is at least partially covering the proximal portion of the body to reduce heat loss from the wafer to the wafer holding assembly.

### BRIEF DESCRIPTION OF THE DRAWINGS

The invention will be more fully understood from the following detailed description taken in conjunction with the accompanying drawings, in which:

FIG. 1A is a perspective view of one embodiment of a wafer-holding pin in accordance with the present invention;

FIG. 1B is a perspective view of another embodiment of a wafer-holding pin in accordance with the present invention;

FIG. 2A is a cross-sectional view of the wafer-holding pin of FIG. 1A;

FIG. 2B is a cross-sectional view of the wafer-holding pin of FIG. 1B;

FIG. 3 is a top view of a wafer-holding pin according to the present invention;

FIG. 4 is a cross-sectional view of another wafer-holding pin in accordance with the present invention;

FIG. 5A is a cross-sectional view of another wafer-holding pin in accordance with the present invention;

FIG. 5B is a perspective view of the wafer-holding pin shown in FIG. 5A;

FIG. 5C is a cross-sectional view of another wafer-holding pin in accordance with the present invention;

FIG. 5D is a perspective view of the wafer-holding pin shown in FIG. 5C;

FIG. 6A is a cross-sectional view of another wafer-holding pin in accordance with the present invention; and

FIG. 6B is a perspective view of the wafer-holding pin shown in FIG. 6A.

### DETAILED DESCRIPTION

The present invention provides a wafer-holding pin that is well-suited for use with SIMOX wafer processing including use of relatively high ion beam energies and temperatures in a vacuum or reduced pressure environment. In general, the wafer-holding pin has a structure that maintains its integrity and reduces the likelihood of wafer damage during extreme conditions associated with SIMOX wafer processing. In some embodiments, the wafer-holding pin can be formed from a thermosetting resin that can be filled with a conductive material to provide an electrical path from the wafer to ground for preventing electrical charging of the wafer, and possible arcing, during the ion implantation process. Portions of the wafer-holding pin can be embedded with graphite to reduce wafer rotation during implantation.

Some embodiments provide wafer-holding pins that are formed of a thermosetting resin material impregnated with a conductive material, such as graphite, so as to provide an electrically conductive path between the wafer and a wafer-holding assembly, and preferably between the wafer and electrical ground. In many embodiments, the thermosetting resin material has a low thermal conductivity so as to inhibit loss of heat from the wafer's edge that is engaged with the pin, e.g., to the wafer-holding assembly, thereby ensuring that the wafer's surface exposed to an ion beam remains substantially isothermal. In many cases, the wafer-holding pin includes a wafer-contacting portion that is formed of a material different than the thermosetting resin that is more suitable for frictionally anchoring the wafer to the pin so as to prevent wafer slippage during ion implantation. Some examples of such materials include graphite and silicon. In some cases, such wafer-contacting portions may have a greater thermal conductivity than the resin. Hence, in some such embodiments, the pin is configured such that heat can be actively transferred to the wafer-contacting portion to inhibit temperature non-uniformity of the wafer's surface exposed to an ion beam, e.g., due to heat loss via the wafer-contacting portion. By way of example, the wafer-contacting portion can be formed by a graphite insert disposed in a distal portion of the pin, where a surface of that insert can be exposed to the ion beam and/or a radiative heat source so as to transfer heat to the wafer in order to substantially offset any heat loss via the wafer-contacting portion.

A wafer holder assembly suitable for use with a wafer-holding pin in accordance with the present invention is disclosed in U.S. Pat. No. 6,794,662 to Leavitt et al., the teachings of which are hereby incorporated by reference.

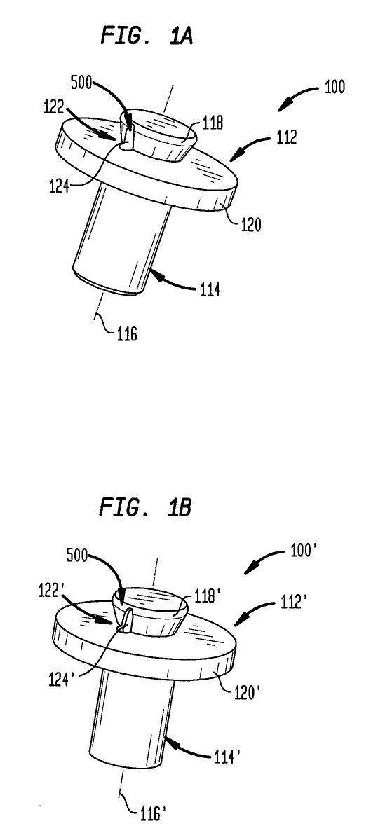

FIGS. 1A and 1B depict exemplary embodiments of wafer-holding pins in accordance with the present invention. In both embodiments, the wafer-holding pin 100, 100′ includes a distal portion 112, 112′ for holding a wafer, a proximal portion 114, 114′ for coupling to a wafer holder arm, and a longitudinal axis 116, 116′ that extends from the distal portion 112, 112′ towards the proximal portion 114, 114′. The proximal portion 114, 114′ can be a post that mates to a wafer holder arm. The distal portion 112, 112′ has a head 118, 118′ coupled to a flange 120, 120′ which is wider than the head. For example, if the pin is generally cylindrical in shape, the flange can have a radius that is greater than (e.g., 1.5 times greater than) the radius of the head 118, 118′. A wafer-receiving groove 122, 122′ with a rounded shape is disposed between the head 118, 118′ and the flange 120, 120′. This roundness or symmetry of the distal portion 112, 112′ provides a curved wafer contact region for securing a wafer regardless of the wafer's direction of approach.

Since the wafer contact area of the distal portion can be uniform on all sides, the requirement for precision during pin alignment is reduced. The wafer contacting area can include an anchoring site 500 for frictionally engaging the wafer. The anchoring site 500 can exhibit a coefficient of friction with the wafer that is greater than the coefficient of friction exhibited between the wafer and the remainder of the pin. For example, in an exemplary embodiment, the anchoring site 500 can be formed from a material having a greater coefficient of friction than the pin material, which is embedded into at least a portion of the wafer contacting area. Various materials can be used for the anchoring site including, for example, graphite and silicon. The anchoring site can provide a “sticking” point for the wafer, thereby reducing wafer rotation during implantation.

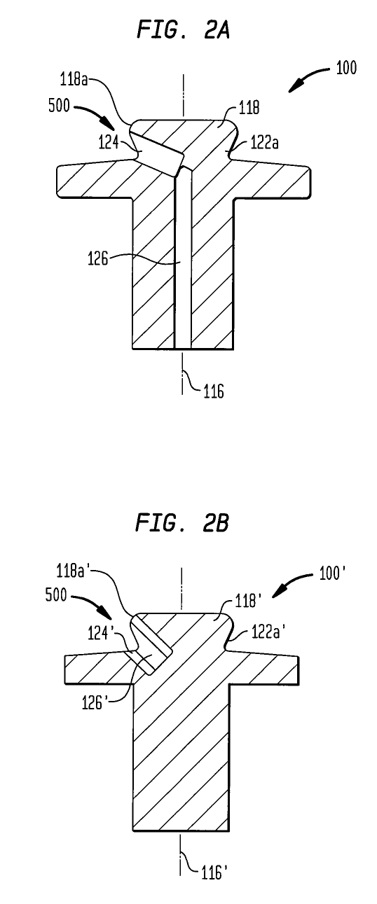

In one embodiment, shown in FIGS. 1A and 2A, the anchoring site 500 is formed by a solid piece of graphite 124 that is embedded into a wafer-holding pin 100. In this embodiment, a bore can be drilled in the pin 100 and the solid piece of graphite 124 can be pressed into the bore achieving a press-fit within the bore. A portion of the graphite is exposed within the wafer-receiving groove so as to be in contact with an edge of a wafer engaged in the groove, to thereby function as an anchoring site for the wafer, i.e., a site inhibiting wafer rotation. The illustrated embodiment includes an optional venting shaft 126 for exhausting air that is forced out of the bore when the graphite 124 is inserted. In another embodiment, shown in FIGS. 1B and 2B, a hollow piece of graphite 124′ can be embedded into a wafer-holding pin 100′. As with the embodiment shown in FIGS. 1A and 2A, a bore can be drilled in the pin 100′ and the hollow piece of graphite 124′ can be pressed into the bore. In this embodiment, however, the hollow piece of graphite 124′ is a C-shaped snap-ring that achieves a snap-fit within the bore. As shown in FIG. 2B, because the embedded graphite 124′ has a hollow center 126′, it is not necessary for the pin 100′ to have a venting shaft. In both embodiments, any excess graphite protruding from the bore after insertion can be trimmed to provide a uniform wafer-receiving groove 122, 122′ profile.

Experimental data illustrates that hybrid pins in accordance with the present invention (e.g., thermosetting resin pins wherein at least a portion of the wafer contacting area comprises graphite) can eliminate or, at least, reduce wafer rotation. For example, a wafer disposed on a conventional wafer-holding pin can rotate as much as 10 degrees, whereas a hybrid pin in accordance with some embodiments of the invention can yield a wafer rotation of zero degrees.

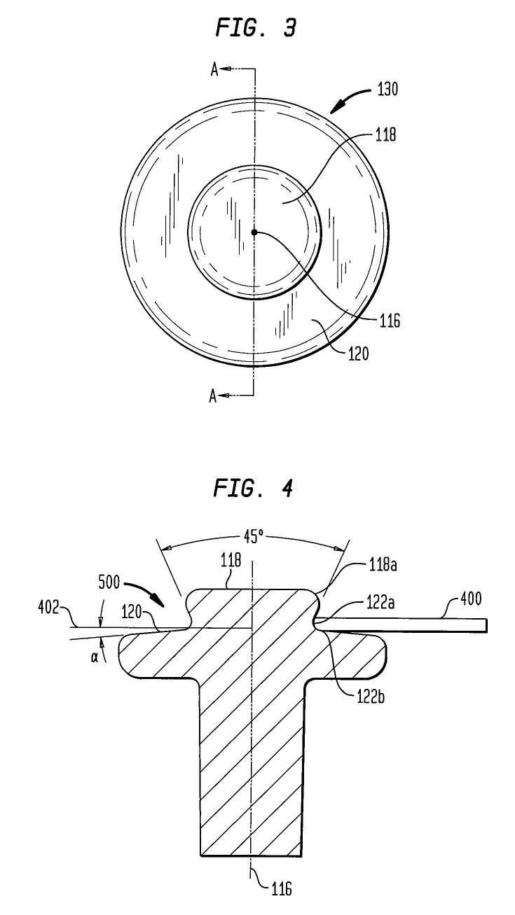

FIG. 3 is a top view of a pin 100, such as is shown in FIG. 1A. The geometry of the pin 100 facilitates wafer placement into the wafer holder, and pin attachment to the wafer holder assembly. Specifically, the geometry of the pin 100 reduces shadowing, reduces electrostatic discharge, and provides for secure wafer gripping while reducing the need for precision when aligning and attaching the pin 100 to a wafer holder arm. As shown in the top view 130, the distal portion can be cylindrical in shape, e.g., cylindrically symmetric about the longitudinal axis 116. (Although the longitudinal axis is depicted in FIG. 1A as running through the body of the pin 100, it should be appreciated that the axis can also be offset such that the pin body does not pass through the axis).

As a result of the symmetry, the distal portion 112 acts as a wafer/pin contact surface that in one embodiment can be uniform on all sides. Regardless of the direction in which a wafer approaches the curved surface 122 the radial symmetry of the distal portion 112 assures secure wafer gripping. In addition to providing secure wafer gripping, the radially symmetric distal portion 112 relaxes the need for precise pin alignment. The pin 100 is able to engage a wafer across a much wider angle of approach. Thus, the radial symmetry reduces the need for precision in aligning the pin 100 when it is attached to the other elements of the wafer-holding assembly.

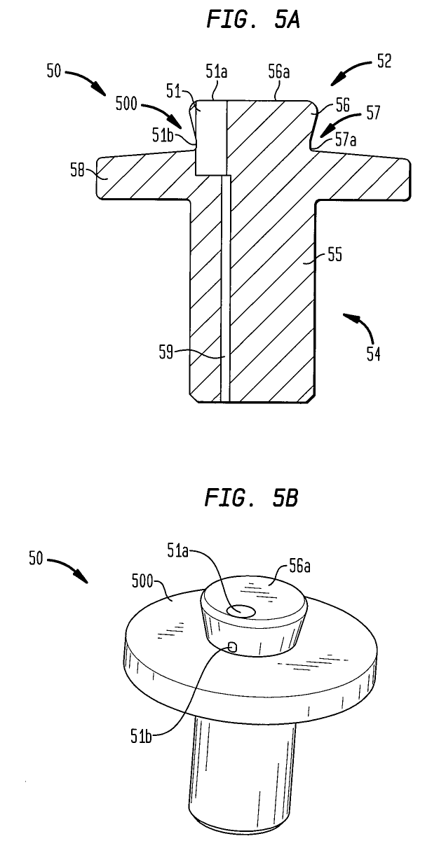

FIGS. 2A-2B and 4 are cross-sectional views of the pins 100, 100′ of FIGS. 1A and 1B with a wafer 400 disposed in the groove 122, 122′. The head 118, 118′ is shown with a rounded edge 118a, 118a′ at a wafer contact point 122a, 122a′ to provide a reduced profile, and to reduce the amount of pin material overlying the wafer edge. As illustrated, the head 118, 118′ tapers to a narrower waist portion at a 45 degree angle with respect to the axis 116, 116′ to form the groove, however the angle can be modified according to the dimensions of the wafer and pin and can range from about 20 degrees to about 60 degrees. The rounded top edge 118a of the head 118, 118′ reduces shadowing by not obstructing the path of the ion beam. This also has the effect of reducing sputtering, which is typically caused by the ion beam striking the pin (or exposed regions of a holder assembly). In addition, the reduced amount of pin material near the wafer edge reduces the electrical arcing between the wafer and the pin 100, 100′ that can occur during the ion implantation process.

The wafer-receiving groove 122, 122′ that is disposed between the head 118, 118′ and the flange 120, 120′ receives and secures the wafer to prevent movement of the wafer. The anchoring site 500 which can be disposed in at least a portion of the wafer-receiving groove 122, 122′ further reduces wafer rotation during implantation. The rounded shape and internal diameter of the groove 122, 122′ preferably allows contact only at the top and bottom of the wafer edge at points 122a, 122b, thereby reducing the contact area between the wafer edge and the curved surface 122, 122′. As shown in FIG. 4, the flange 120, 120′ slopes downward at an angle a relative to an axis 402 that is perpendicular to the longitudinal axis 116 of the pin. The angle α that defines the downward slope of the flange 120, 120′ can be modified according to the thickness of the wafer size and of the groove but can generally range from about 2 degrees to about 8 degrees. Such a configuration can further reduce contact between the wafer and the pin 100, 100′.

Those skilled in the art will appreciate that the uniform contact surface, as shown and discussed above, is only presented as an example. Pin structures having wafer contact surfaces that are not uniform on all sides can still fall within the scope of the invention. For example, a wafer contact surface can extend for an azimuthal angle of less than 360 degrees, e.g., at least 10 degrees.

In a preferred embodiment, the wafer-holding pins are manufactured of a material comprising a thermosetting polyimide resin. These materials can have excellent mechanical properties such as low friction, good hardness, are easy to machine and contain little, if any, metals. As explained in Leavitt, thermosetting polymers can withstand temperatures of 600° C., or higher, without degradation when placed in service under vacuum conditions. Thus, wafer-holding pins comprising a thermosetting resin can be used within ion implanters, such as in SIMOX applications.

One preferred class of polymers useful in the present invention are polyimides because of their excellent heat resistance, chemical resistance and mechanical properties. Polyimides can be obtained by the polycondensation of an aromatic carboxylic acid with an aromatic amine. One resin used herein has an imide bond in its main chain, however, polyamideimide resins having an imide bond and an amide bond in its main chain can also be used. Vespel® polyimides (Dupont, Wilmington, Del.) and particularly, the Vespel® SCP family of resins are examples of polymeric materials useful in the present invention.

The polyimide resins disclosed herein do not melt or otherwise degrade under the high temperature conditions that occur in an ion implantation chamber and they can exhibit good frictional and abrasion characteristics over a wide temperature range to secure the wafer. Further, the cured resins have sufficient softness to not cause marking on the wafer, yet have sufficient hardness to hold the wafer without significant crushing or conformity to the edge of the wafer. For example, in a preferred embodiment, the resin has a hardness between about 7 and about 1 on the Mohs' scale of hardness, yet are at least sufficiently hard to prevent the pin from crushing under the forces necessary to secure the wafer. More preferably, the hardness can range from about 6 to about 2 on the Mohs' scale. Generally speaking, the hardness should be less than about 6 on the Mohs' scale.

It will be understood that pins conforming to the wafer edge can cause localized heat differentials during heating of the wafer. Thus, the polyimide resins disclosed are sufficiently thermally insulative to eliminate or substantially mitigate localized cooling during wafer processing. In a preferred embodiment, for example, the resin can have thermal conductivity between about 3.0 W/m deg. K and about 0.01 W/m deg. K. Generally speaking, the thermal conductivity of the resin should be below about 2.0 W/m deg. K. However, in many embodiments, the resin can be impregnated with an electrically conductive material, such as graphite, to provide an electrically conductive path from the wafer to the wafer-holding arm, and preferably to ground.

Experimental data illustrates that a hybrid pin in accordance with the present invention has an overall thermal signature that is significantly more uniform than that of a conventional graphite pin. Thus, embedding a small amount of graphite into a thermosetting resin pin reduces wafer rotation during implantation while maintaining the desired overall thermal signature provided by the thermosetting resin.

The terms “thermosetting resin,” “thermoset polymers” and similar variations, as used herein, are intended to encompass polymeric materials that harden when heated and cannot be easily remolded. Such resins include, but are not limited to, Polyimides (e.g., Vespel®), Polyetheretherketones (e.g., PEEK-HT® and PEEK-COPYEXACT®), Polyamide-imides (e.g., Torlon®), Polybenzimidazoles (e.g., Celazole™), and Polyetherimides (e.g., Ultem®).

Thermosetting resins are generally not, however, electrically conductive and when used in pure form may induce charge build-up and subsequent arcing between the wafer and other elements within an ion implantation chamber. In implantation systems, the resins used herein can be filled with an electrically conductive material to create a electrical path between the wafer and the wafer-holding arms to reduce or eliminate the risk of arcing. Suitable materials for this purpose include metals or metallic compositions. In certain embodiments, the conductive filler can be elemental carbon or silicon. Alternatively, or in addition, the resin pin can be coated with an electrically conductive coating. The pins can have an electrical bulk resistivity between about 150 ohms-cm and about 10 ohms-cm. More generally, the pins have a bulk resistivity below about 100 ohms-cm, and thus can prevent or substantially mitigate electrical arcing.

The hybrid pins disclosed herein reduce the likelihood of wafer contamination because the ion beam strikes only silicon thereby minimizing carbon contamination and particle production. Experimental data illustrates that hybrid pins yield low post-implantation particle counts.

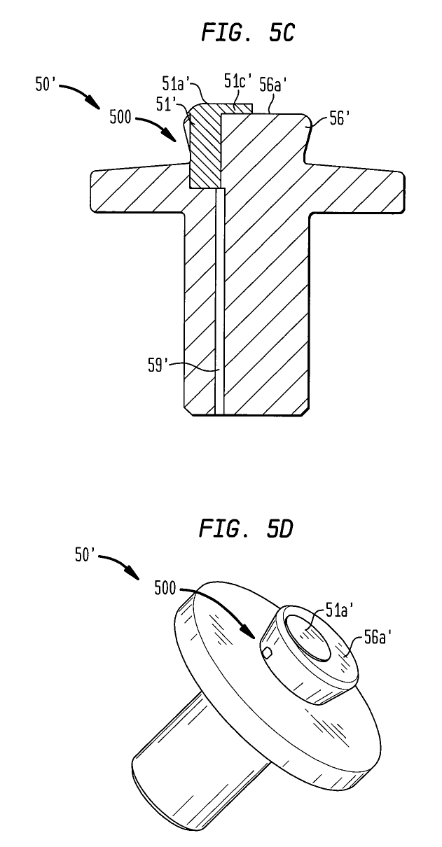

FIGS. 5A and 5B schematically depict a wafer-holding pin 50 in accordance with another embodiment of the invention that includes a distal portion 52 to which a wafer can be engaged so as to be held in a path of an ion beam and a proximal portion 54 for coupling the pin to a wafer-holding assembly, e.g., a wafer-holding arm. More specifically, the distal portion 52 includes a head 56 that extends to a flange 58, where the junction of the head with the flange forms a groove 57 characterized by a curved inner surface 57a for receiving a wafer and securing it to the distal portion. Further, the proximal portion 54 includes a shaft 55 that extends longitudinally from the head 56 and is adapted for coupling the pin to a wafer-holding assembly. In this embodiment, the proximal and the distal portions 54, 52 are formed from a thermosetting resin material, such as those discussed above in connection with the previous embodiments, as an integral unit—though in other embodiments the distal and proximal portions 54, 52 can be formed as separate structures that are joined together.

With continued reference to FIGS. 5A and 5B, the wafer-holding pin 50 further includes an insert 51, formed of a thermally conductive material, that is disposed in the pin's distal portion 52 such that a top surface 51a thereof can be exposed to a heat source and a side surface portion 51b thereof can be exposed within the groove, e.g., to form part of the inner surface of the groove 57a. In many embodiments, the ion beam itself can function as the heat source via bombardment of the top surface 51a of the insert 51. Alternatively, or in addition, a heat lamp (or other suitable device) can transfer heat energy to the insert via its exposed top surface 51a.

In this manner, the insert 51 can provide a thermal path for transferring heat to the wafer, thereby minimizing, and preferably eliminating, temperature variations that might otherwise occur over the wafer's surface that is exposed to an ion beam, especially between the areas in the vicinity of the wafer's edge engaged with the pin and the rest of the surface. In addition, in many embodiments, the contact of wafer's edge, when engaged within the groove 57, with the surface portion 51b of the insert 51 can function as an anchoring mechanism to frictionally inhibit the wafer's rotation, e.g., in a manner discussed above in connection with some of the previous embodiments.

A variety of configurations are available for the insert 51. In the embodiments shown in FIGS. 5A and 5B, the insert 51 is in the form of a cylinder that can be snap-fit within a bore in the pin's distal portion 52, which extends longitudinally from the top surface 56a of the head 56 to the flange 58 and provides an opening to the groove 57. The size and shape of the insert 51 can also vary. For example, as shown in FIG. 5A, the top surface 51a of the insert is flush with the top surface 56a of the head 56 of the pin 50. In another exemplary embodiment, shown in FIGS. 5C and 5D, the top surface 51a′ of the insert 51′ includes a lip or flange 51c′ that extends over the top surface 56a′ of the head 56′ of the pin 50′. The flange 51c′ can increase the collection area of the insert 51′ (i.e., the portion of the insert 51′ that is exposed to the heat source) and thereby further decrease temperature variations over the wafer's surface.

By way of example, the insert 51 can be formed of graphite or silicon. More generally, the insert 51 can be formed of a material that is able to withstand exposure to an ion beam and has an electrical resistivity that is preferably greater than about 7.5 micro Ohm-meters.

In this embodiment, the head 56, the flange 58 and the shaft 55 are formed as an integral unit from a thermosetting resin material, such as those discussed above. The thermosetting material has preferably a lower thermal conductivity than the insert 51. More generally, the thermosetting resin material is sufficiently thermally insulative so as to reduce, and preferably eliminate, heat loss from the wafer to the wafer holder assembly. In some cases, the thermosetting material is impregnated with an electrically conductive material, e.g., graphite, such that the pin would provide an electrically conductive path from the wafer to the wafer holder assembly while concurrently inhibiting heat loss from the wafer.

With continued reference to FIGS. 5A-5D, the pin 50, 50′ can further include an optional venting shaft 59, 59′ that can function as an exhaust for air that is forced out of the bore when the thermally conductive insert is disposed therein.

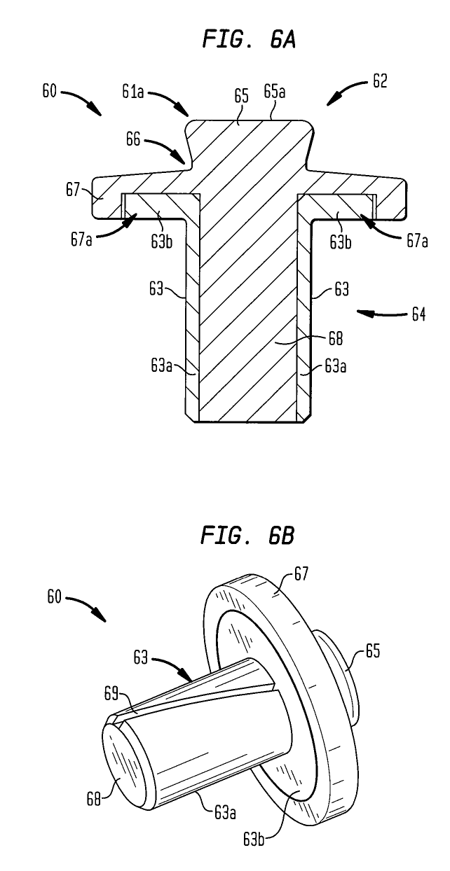

FIGS. 6A and 6B schematically illustrate a wafer-holding pin 60 according to another embodiment of the invention that includes a distal portion 62 to which a wafer can be coupled to be in a path of an ion beam and a proximal portion 64 that can be connected to a wafer holder assembly (not shown). The pin 60 comprises a body 61 that is formed of an electrically conductive material, e.g., a material exhibiting an electrical resistivity that is preferably greater than about 7.5 micro Ohm-meters, and a sheath 63 that surrounds at least a portion of the body 61. The sheath 63 is formed of a material having a lower thermal conductivity than that of the body 61. For example, the sheath 63 can be formed of a thermally insulating material, which as used herein refers to a material exhibiting a thermal conductivity less than about 2.0 W/m deg. K.

The body 61 includes a distal portion 61a, composed of a head 65 extending to a flange 67, where a junction of the head and the flange forms a groove 66 in which an edge of a wafer can be engaged. The body further includes a shaft 68 that extends longitudinally from the head 65. In this embodiment, the head 65 is adapted such that it can be exposed, e.g., via a top surface 65a thereof, to a source of heat, e.g., the ion beam itself that can impart heat to the head via ion impact and/or a radiative heat source such as a lamp. The thermally conductive material forming the head 65 and the flange 67 provides a thermal path from the head 65 to the wafer engaged within the groove 66 so as to transfer heat to the wafer. Such transfer of heat to the wafer can advantageously minimize, and preferably eliminate, temperature variations that might occur over the wafer's surface that is exposed to the ion beam, e.g., a result of heat loss from the wafer's edge to the pin.

With continued reference to FIGS. 6A and 6B, the sheath 63 is formed of a hollow cylindrical portion 63a that extends to a flange portion 63b. The sheath 63 can be coupled to the body 61 by inserting the shaft 68 into the cylindrical portion 63a of the sheath 63 and snap-fitting the sheath's flange 63b into a mating groove 67a formed in the body's flange 67. In this manner, a thermal contact is achieved between the body 61 and the sheath 63. As shown in FIG. 6B, a slit 69 is cut in the sheath 63 to account for varying coefficients of thermal expansion between the sheath 63 and the body 61. The sheath is formed, in many embodiments, of a material exhibiting a low thermal conductivity can inhibit heat loss from the wafer, e.g., to a wafer holder assembly. In particular, the sheath forms the outer layer of the proximal portion of the pin that will be in contact with the wafer holder assembly, thereby thermally insulating the pin's body from the assembly.

In this embodiment, the body 61 of the pin 60 is formed of graphite—though in other embodiments silicon can be utilized—and the sheath 63 is formed of a thermosetting resin material, such as those discussed above. In this embodiment, the graphite body 61 is not only thermally conductive but it is also electrically conductive so as to provide an electrically conductive path from the wafer to the ground to prevent electrical charging of the wafer, and possibly arcing, during ion implantation.

The wafer-holding pin of the present invention provides a structure that withstands the relatively high temperatures and ion beam energies associated with SIMOX wafer processing. The anchoring site reduces wafer rotation during implantation while maintaining the desired overall thermal signature provided by the thermosetting resin. In addition, the likelihood of wafer contamination is reduced since in many embodiments the ion beam strikes only silicon thereby minimizing carbon contamination and particle production. Furthermore, the likelihood of the electrical discharge from the wafer is minimized due to the selection of conductive materials/coatings for the assembly components and/or the geometry of the wafer-holding pins.

Although described primarily in conjunction with ion implantation processes, it should be appreciated that the wafer-holding structures of the present invention can be used in other high temperature semiconductor or material processes, such as plasma deposition, reactive ion deposition, high temperature chemical vapor deposition, sputtering and the like. One skilled in the art will also appreciate further features and advantages of the invention based on the above-described embodiments. Accordingly, the invention is not to be limited by what has been particularly shown and described, except as indicated by the appended claims. All publications and references cited herein are expressly incorporated herein by reference in their entirety.

What is claimed is:

1. A wafer-holding pin for use in an ion implantation system, comprising:
a distal portion adapted to hold a wafer during exposure to an ion beam, the distal portion comprising a thermosetting resin material able to withstand the ion beam and further comprising an anchoring site for frictionally engaging the wafer; wherein said anchoring site comprises a material exhibiting a coefficient of friction with the wafer greater than a respective coefficient exhibited by said resin material,
a proximal portion adapted to couple with a wafer-holding assembly.

2. The wafer-holding pin of claim 1, wherein said anchoring site material is selected from the group consisting of graphite and silicon.

3. The wafer-holding pin of claim 2, further comprising an electrically conductive material dispersed within said thermosetting resin material for providing an electrical pathway between the wafer and the wafer-holding assembly.

4. The wafer-holding pin of claim 3, wherein said electrically conductive material comprises a metallic composition.

5. The wafer holding pin of claim 3, wherein said electrically conductive material comprises graphite.

6. The wafer-holding pin of claim 5, wherein the pin has an electrical resistivity less than about 100 ohms-centimeter.

7. The wafer-holding pin of claim 1, wherein the distal portion comprises a head coupled to a flange with a wafer-receiving groove therebetween, wherein the groove is adapted to engage an edge of the wafer and has a curved inner surface.

8. The wafer-holding pin of claim 7, wherein at least a portion of the groove comprises said anchoring site.

9. The wafer-holding pin of claim 7, wherein the head tapers to a narrow waist portion at an angle in a range of about 20 degrees to about 60 degrees.

10. The wafer-holding pin of claim 7, wherein the flange slopes downward relative to an axis that is perpendicular to a longitudinal axis of the pin at an angle in a range of about 2 degrees to about 8 degrees.

11. The wafer-holding pin of claim 1, wherein said resin material has a thermal conductivity below approximately 2.0 W/m deg. K.

12. The wafer-holding pin of claim 1, wherein the pin has a hardness of approximately equal to or less than that of the wafer.

13. The wafer-holding pin of claim 1, wherein the pin has a hardness of below approximately 6 on Mohs' hardness scale.

14. The wafer-holding pin of claim 1, wherein said resin material can withstand an oxygen ion beam without substantial oxidation.

15. The wafer-holding pin of claim 1, wherein said ion implantation system is selected from the group consisting of a plasma etch system, a plasma stripping system and an ion deposition system.

16. A wafer-holding pin, comprising:
a distal portion for holding a wafer, the distal portion comprising a thermosetting resin material suitable for use in a vacuum environment at a temperature in a range of about 0° C. and about 650° C. and able to withstand an oxygen ion beam without substantial oxidation, the distal portion being electrically conductive to provide an electrical pathway between the wafer and a wafer-holding assembly,
a proximal portion adapted to couple to the wafer-holding assembly; and
a longitudinal axis extending from the distal portion towards the proximal portion,
the distal portion having a head coupled to a flange with a wafer-receiving groove therebetween, the groove being adapted to engage an edge of the wafer and having a curved inner surface, wherein at least a portion of the said inner surface is formed of a material that is different than said resin and that is suitable for frictionally securing said wafer to the distal portion.

17. The wafer-holding pin of claim 16, wherein said material of the wafer-contacting surface comprises any of graphite or silicon.

18. The wafer-holding pin of claim 17, wherein the inner surface exhibits radial symmetry about an axis for an azimuthal angle of at least 10 degrees.

19. The wafer-holding pin of claim 16, wherein the flange is wider than the head.

20. The wafer-holding pin of claim 16, wherein the distal portion further includes an electrically conductive filling.

21. The wafer-holding pin of claim 20, wherein the electrically conductive filling is carbon.

22. A wafer-holding pin for use in an ion implanter, comprising:
a distal portion comprising a wafer-receiving groove,
a proximal portion adapted for coupling with a wafer-holding assembly, and
a thermally conductive insert disposed in said distal portion such that a surface portion of said insert provides an anchoring site for the wafer in the groove,
wherein said insert provides a thermal path for transferring heat to the wafer.

23. The wafer-holding pin of claim 22, wherein a surface of the insert is exposed to an ion beam in the ion implanter such that ion impact heats up the insert.

24. The wafer-holding pin of claim 22, wherein a surface of the insert is adapted for exposure to a radiative heat source.

25. The wafer-holding pin of claim 22, wherein said distal portion comprises a thermosetting resin.

26. The wafer-holding pin of claim 25, wherein said insert exhibits a thermal conductivity greater than that of said resin.

27. The wafer-holding pin of claim 22, wherein said insert comprises a material selected from the group consisting of graphite and silicon.

28. The wafer-holding pin of claim 22, wherein said distal portion comprises a head extending to a flange such that said groove is formed at a junction of the head and the flange, and said proximal portion comprises a shaft longitudinally extending from the head.

29. A wafer-holding pin for use in an ion implanter, comprising:
a body having an electrically conductive distal portion for holding a wafer in a path of an ion beam, said distal portion providing a thermal path for transferring heat to the wafer and a proximal portion adapted for coupling with a wafer holding assembly, and
a sheath at least partially covering said proximal portion to reduce heat loss from the wafer to the wafer holding assembly.

30. The wafer-holding pin of claim 29, wherein said sheath is thermally insulating.

31. The wafer-holding pin of claim 29, wherein said sheath comprises a thermosetting resin material.

32. The wafer-holding pin of claim 29, wherein said body is formed of a material selected from the group consisting of silicon and graphite.

33. The wafer-holding pin of claim 29, wherein said distal portion of the body comprises a head extending to a flange, wherein a junction of said head with the flange forms a groove for engaging an edge of the wafer.

34. The wafer-holding pin of claim 33, wherein said proximal portion comprises a shaft extending longitudinally from said head.

35. The wafer-holding pin of claim 34, wherein said sheath comprises a substantially cylindrical portion surrounding said shaft.

36. The wafer-holding pin of claim 35, wherein said sheath further comprises a flange portion that is in thermal contact with the flange of said distal portion of the body.
